(19) United States
(12) Patent Application Publication
(10) Pub. No.: US 2025/0183209 A1
(43) Pub. Date: Jun. 5, 2025

(54) SEMICONDUCTOR DEVICE WITH SELF-ALIGNED COMPONENT AND METHOD OF FORMING THE SAME

(71) Applicants: Asphetek Solution (Chengdu) Ltd., Chengdu (CN); ADVANCED OPTOELECTRONIC TECHNOLOGY, INC., Hsinchu County (TW); Asphetek Solution Inc., Hsinchu (TW)

(72) Inventors: Yuan-Ting Liang, Hsinchu (TW); Chung-Wu Liu, Hsinchu (TW)

(21) Appl. No.: 18/667,122

(22) Filed: May 17, 2024

(30) Foreign Application Priority Data
Nov. 30, 2023 (CN) 202311629289.9

(51) Int. Cl. H01L 23/00

(52) U.S. Cl. CPC H01L 24/06; H01L 24/03; H01L 24/08; H01L 2224/03831; H01L 2224/03849; H01L 2224/0603; H01L 2224/06132; H01L 2224/08148; H01L 2924/381

(57) ABSTRACT

A semiconductor device comprises a component, a circuit board, a first solder material, and a second solder material. The component comprises many first pads and at least one first auxiliary pad spaced from the first pads on a mating surface of the component, and a distance between the first auxiliary pad at the first preset position and a center of gravity of the component is the longest compared to the first pads. The first auxiliary pad is located on a first preset position of the mating surface. The circuit board comprises many second pads and a second auxiliary pad spaced from the second pads on a mating surface. The first solder material is connected between the first pads and the second pads. The second solder material is connected between the first auxiliary pad and the second auxiliary pad. A method of forming a semiconductor device is also provided.

### FIELD

This disclosure relates generally to semiconductor device packaging, and more specifically, to a semiconductor device with self-aligned component and method of forming the same.

### BACKGROUND

With the rapid development of the semiconductor industry, the application of packaging technology is increasingly broad, more diverse forms of packaging. Wherein, Flip-Die technology is both a die interconnection technology, but also a more ideal die bonding technology.

In the connection of a circuit board and a component, firstly, applying solder material to the mating surfaces of the circuit board or the component, then the solder material is heated by means of reflow soldering to melt the solder material, and the melted solder material connects the pads on the mating surface of the circuit board and the pads on the mating surface of the component after curing. However, the offset of the component relative to the circuit board in this connection method is relatively small, which cannot meet the requirements of high precision packaging of the component in some scenarios. Therefore, there is room for improvement within the art.

### BRIEF DESCRIPTION OF THE DRAWINGS

Implementations of the present technology will now be described, by way of example only, with reference to the attached figures, wherein:

FIG. 1 is a schematic view of a semiconductor device in an embodiment of the disclosure.

FIG. 2 is a cross-sectional view of the semiconductor device in FIG. 1 along II-II.

FIG. 3 is a schematic view of a structure of a component, a first pad and a first auxiliary pad of the semiconductor device in a first embodiment of the disclosure in FIG. 1.

FIG. 4 is a schematic view of a structure of a component, a first pad and a first auxiliary pad of the semiconductor device in a second embodiment of the disclosure in FIG. 1.

FIG. 5 is a schematic view of a structure of a component, a first pad and a first auxiliary pad of the semiconductor device in a third embodiment of the disclosure in FIG. 1.

FIG. 6 is a schematic view of a portion of a structure of a circuit board, a second auxiliary pad, and a structure of the second pad of the semiconductor device in the first embodiment of the disclosure in FIG. 1.

FIG. 7 is a schematic view of a portion of a structure of a circuit board, a second auxiliary pad, and a structure of the second pad of the semiconductor device in the second embodiment of the disclosure in FIG. 1.

FIG. 8 is a schematic view of a portion of a structure of a circuit board, a second auxiliary pad, and a structure of the second pad of a semiconductor device in the third embodiment of the disclosure in FIG. 1.

FIG. 9 is a flowchart of a manufacturing method of a semiconductor device in an embodiment of the disclosure.

### DETAILED DESCRIPTION

It will be appreciated that for simplicity and clarity of illustration, where appropriate, reference numerals have been repeated among the different figures to indicate corresponding or analogous elements. Additionally, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

When a feature or element is herein referred to as being “on” another feature or element, it can be directly on the other feature or element or intervening features and/or elements may also be present. It will also be understood that, when a feature or element is referred to as being “connected” or “attached” to another feature or element, it can be directly connected, attached, or coupled to the other feature or element or intervening features or elements may be present.

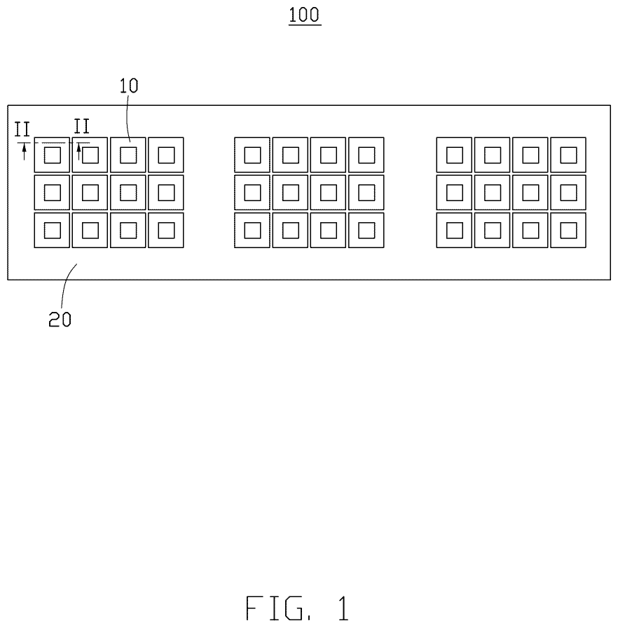

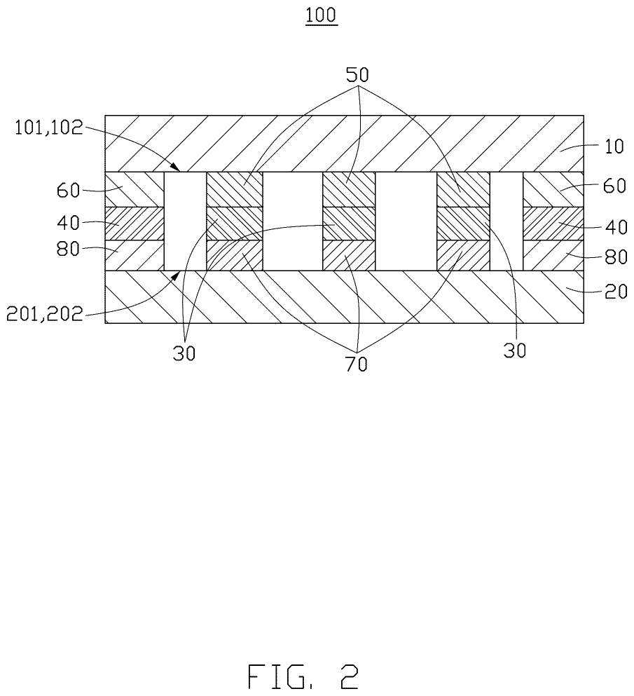

In FIG. 1 and FIG. 2, a semiconductor device 100 is provided by an embodiment of the disclosure. The semiconductor device 100 comprises a plurality of components 10, a circuit board 20, a first solder material 30, and a second solder material 40.

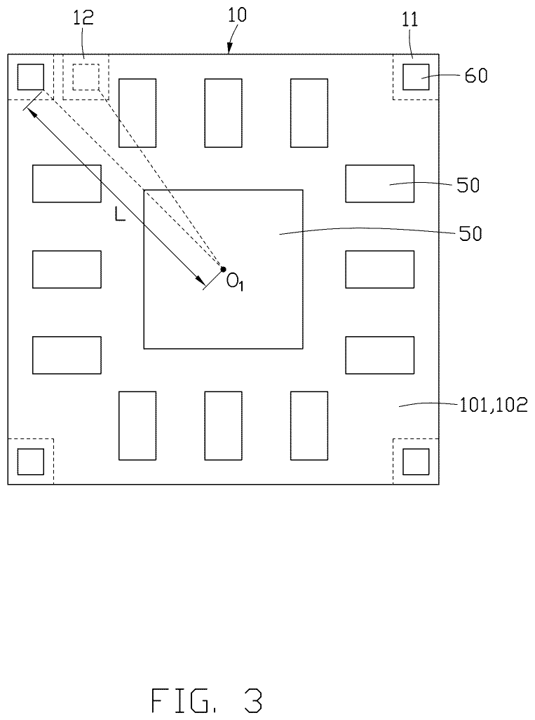

In FIG. 1, FIG. 2 and FIG. 3, the component 10 is provided with a plurality of first pads 50 and four first auxiliary pads 60 spaced apart from the plurality of first pads 50 on a mating surface 101 of the component 10, the first auxiliary pad 60 is located on a first preset position 11 of the mating surface 101 of the component 10, and a distance L between the first auxiliary pad 60 at the first preset position 11 and a center of gravity O1 of the component 10 is the longest compared to the first pads 50. The circuit board 20 is provided with a plurality of second pads 70 and four second auxiliary pads 80 spaced apart from the plurality of second pads 70 on a mating surface 201 of the circuit board 20, the plurality of second pads 70 are correspondingly placed with the plurality of first pads 50, and the second auxiliary pad 80 is correspondingly placed with the first auxiliary pad 60. the first solder material 30 connected between the plurality of first pads 50 and the plurality of second pads 70, the second solder material 40 connected between the first auxiliary pads 60 and the second auxiliary pads 80, wherein each of the plurality of second pads 70 is aligned with a corresponding first pads of the plurality of first pads 50, and the second auxiliary pads 80 are respectively aligned with the first auxiliary pads 60 by a solder connection.

It can be understood that, the first preset positions 11 is formed by the two dashed lines in FIG. 3 and the two side edges of the component 10 enclosed, the other positions 12 is formed by the three dashed lines in FIG. 3 and one of the side edges of the component 10 enclosed, comparing with one pad at the other positions 12 of the component 10, the distance L between the first auxiliary pad 60 at the first preset position 11 and the center of gravity O1 of the component 10 is the longest compared to the first pads 50.

It can be understood that, the other positions 12 in FIG. 3 are only an example of one of the different positions distinguishing the first preset position 11 and do not serve as a limitation of the specific positions in the present embodiment, and the first preset position 11 is viewed as a whole, in other words, comparing with an element at the other positions 12 of the component 10, the distance L between the element at the first preset position 11 and the center of gravity O1 of the component 10 is the longest.

Of the above semiconductor device 100, the first auxiliary pads 60 located on the first preset position 11 are able to provide the maximum rotational torque for the component 10 to rotate with respect to the circuit board 20, thereby improving the self-alignment of the component 10 and the circuit board 20, thus improving the encapsulation accuracy of the component 10 and the circuit board 20, and to a certain extent, it is also possible to expand the packaging scenarios for component 10.

The component 10 is a single bare component that is not encapsulated after the wafer has been thinned and cut, such as a light emitting diode component.

The circuit board 20 is made of an epoxy resin copper laying circuit board, a polyimide copper laying circuit board, a flexible circuit board, or a polyethylene terephthalate circuit board.

The material of the first solder material 30 is one of tin, silver, indium or tin alloys, the material of the second solder material 40 is one of tin, silver, indium or tin alloys, the first solder material 30 and the second solder material 40 are made of the same material, for example, both the first solder material 30 and the second solder material 40 are made of tin alloys.

In FIG. 2 and FIG. 3, the component 10 is square shaped. Wherein one of the plurality of first pads 50 is located on a center of the mating surface 101 of the component 10, and the other plurality of first pads 50 are provided around the first pad 50 that is located on the center of the component 10, wherein the first pad 50 located on the center of the component 10 has a larger bottom surface area, the other plurality of first pads 50 all have equal bottom surface areas.

The material of the first pad 50 is one of gold, copper, silver, aluminum and tin. In this way, the electrical conductivity and connection effect of the first pad 50 can be ensured.

The four first auxiliary pads 60 are respectively located on the four corners of the mating surface 101 of the component 10. In this way, the distribution of the first auxiliary pads 60 on the component 10 is more uniform, and the solder can provide a more consistent force for the component 10 to rotate with respect to the circuit board 20 when the solder is melted.

The material of the first auxiliary pad 60 is one of gold, copper, silver, aluminum and tin. In this way, the electrical conductivity and connection effect of the first auxiliary pad 60 can be ensured.

The plurality of first pads 50 and the at least one first auxiliary pad 60 have an equal height relative to the mating surface 101 of the component 10. In this way, the flatness of the surface of the component 10 after soldering can be ensured.

The first pads 50 and the first auxiliary pads 60 are made of the same material. In this way, it is possible to fabricate the first pads 50 and the first auxiliary pads 60 simultaneously on the component 10, and the fabrication of the first pads 50 and the first auxiliary pads 60 is short time-consuming and efficient.

The first auxiliary pads 60 are square shaped. A ratio of an area of the any one of first auxiliary pads 60 to an area of one of the plurality of first pads 50 is in a range from 0.01 to 5. In this way, it is possible to ensure that the area of the auxiliary pad provides sufficient rotational torque but is not so large as to take up space on the surface of the component 10.

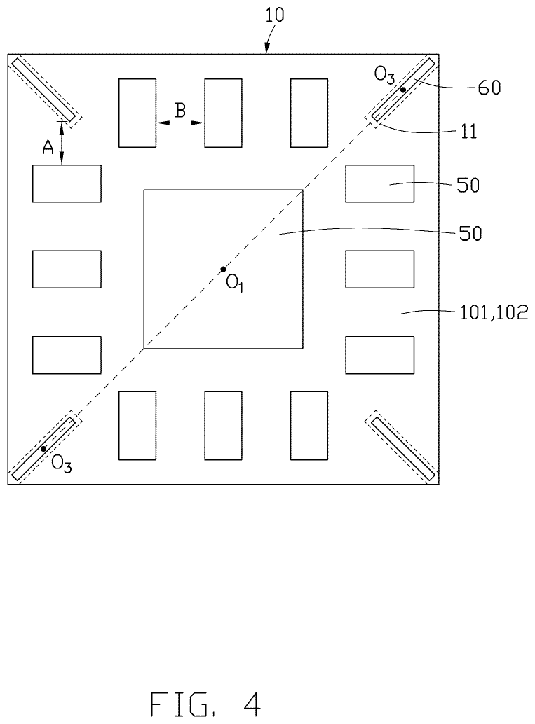

In FIG. 4, the first auxiliary pad 60 is rectangular shaped, wherein centers of gravity O3 of at least two of the plurality of first auxiliary pads 60 are located on two opposite corners in a diagonal direction of the component 10, and centers of gravity O3 of at least two of the plurality of first auxiliary pads 60 and a center of gravity O1 of the first pad 50 located on the center of the component 10 are in a straight line. In this way, it is possible to enable the first auxiliary pads 60 at the corners of the component 10 to provide the maximum rotational torque during soldering.

A minimum spacing value between one of the plurality of first pads 50 and the at least one first auxiliary pad 60 is A, the semiconductor device 100 comprises the plurality of first pads 50, a spacing value between any two of the plurality of first pads 50 is B, wherein a ratio of A to B is in a range from 0.1 to 3. In this way, it can be ensured that the first pad 50 and the first auxiliary pad 60 will not be conducted during the soldering process due to the melting of the solder, thereby preventing short circuit or adverse effects to the self-alignment effect from occurring within the component 10.

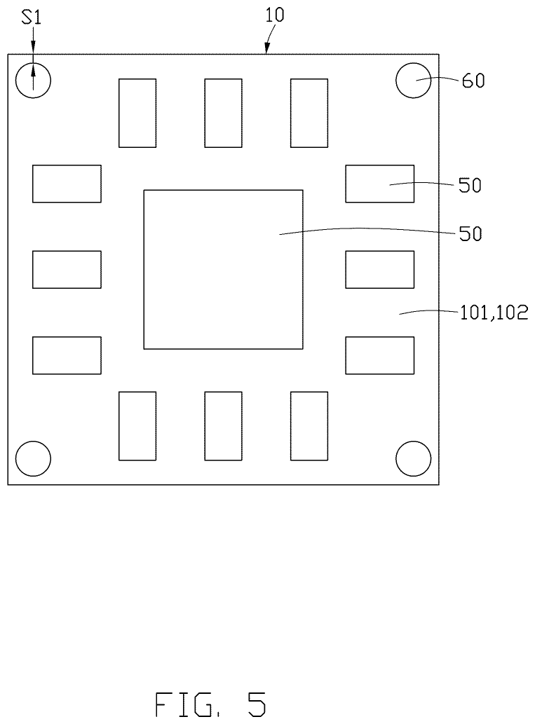

In FIG. 5, the first auxiliary pad 60 is round shaped, in order to avoid short circuit of elements on the component 10, a distance S1 between the at least one first auxiliary pad 60 and an edge of the component 10 is in the range of less than or equal to 3 mm. When the distance S1 between the first auxiliary pad 60 and the edge of the component 10 is greater than 3 mm, the first auxiliary pad 60 generates a smaller rotational moment. Additionally, when the gap existing between the first auxiliary pad 60 and the edge of the component 10 is less than or equal to 3 mm, the first auxiliary pad 60 at the edge of the component 10 is not easily peeled off when the component 10 is cut.

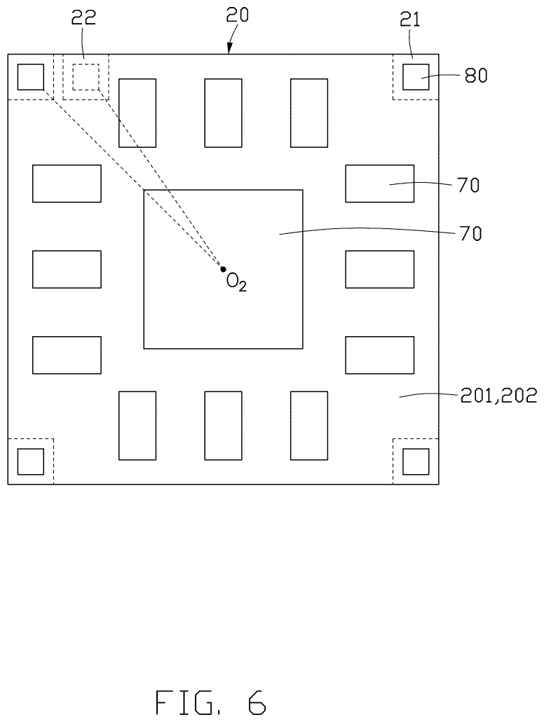

In FIG. 2 and FIG. 6, the circuit board 20 shown in FIG. 6 is a partial structure of the circuit board 20 of FIG. 1, which is square and is provided in correspondence with the component 10. In the partial structure of the circuit board 20 shown in FIG. 6, wherein one of the plurality of second pads 70 is located on a center of the mating surface 201 of the circuit board 20, and the other plurality of second pads 70 are provided around the periphery of the second pad 70 that is located on the center of the circuit board 20, wherein the second pad 70 located on the center of the circuit board 20 has a larger bottom surface area, the other plurality of second pads 70 all have equal bottom surface areas.

The material of the second pad 70 is one of gold, copper, silver, aluminum and tin. In this way, the electrical conductivity and connection effect of the second pad 70 can be ensured.

In this embodiment, the four second auxiliary pads 80 are respectively located on the four corners of the circuit board 20. In this way, the second auxiliary pads 80 are more evenly distributed across the circuit board 20 to be located opposite each of the four first auxiliary pads 60.

The material of the second auxiliary pad 80 is one of gold, copper, silver, aluminum and tin. In this way, the electrical conductivity and connection effect of the second auxiliary pad 80 can be ensured.

The plurality of second pads 70 and the at least one second auxiliary pad 80 have an equal height relative to the mating surface of the circuit board 20. In this way, the flatness of the surface of the circuit board 20 after soldering can be ensured.

The second pad 70 and the second auxiliary pad 80 are made of the same material. In this way, it is possible to fabricate the second pad 70 and the second auxiliary pad 80 at the same time on the circuit board 20, and the fabrication of the second pad 70 and the second auxiliary pad 80 is short time-consuming and highly efficient.

The second auxiliary pad 80 is located on a second preset position 21 of the mating surface of the circuit board 20, the second preset position 21 corresponds the first preset position 11 in FIG. 2.

In this embodiment, the second auxiliary pad 80 is square shaped. A ratio of an area of the at least one second auxiliary pad 80 to an area of one of the plurality of second pads 70 is in a range from 0.01 to 5. In this way, it is possible to ensure that the area of the auxiliary pad provides sufficient rotational torque but is not so large as to take up space on the surface of the circuit board 20.

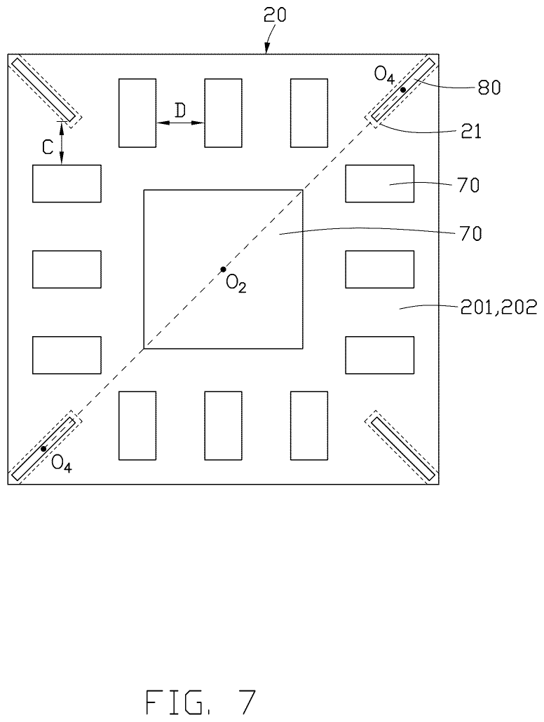

In FIG. 7, the second auxiliary pad 80 is rectangular shaped, wherein centers of gravity O4 of at least two of the plurality of second auxiliary pads 80 are located on two opposite corners in a diagonal direction of the circuit board 20, and centers of gravity O4 of at least two of the plurality of second auxiliary pads 80 and a center of gravity O2 of the second pad 70 located on the center of the circuit board 20 are in a straight line. In this way, it is possible to have a maximum rotational moment at the corners of the component 10 during soldering.

A minimum spacing value between one of the plurality of second pads 70 and the at least one second auxiliary pad 80 is C, the semiconductor device 100 comprises the plurality of second pads 70, a spacing value between any two of the plurality of second pads 70 is D, wherein a ratio of C to D is in a range from 0.1-3. In this way, it can be ensured that the second pad 70 and the second auxiliary pad 80 will not be conducted during the soldering process due to the melting of the solder, thereby preventing short circuit within the circuit board 20 or adverse effects to the self-alignment effect from occurring.

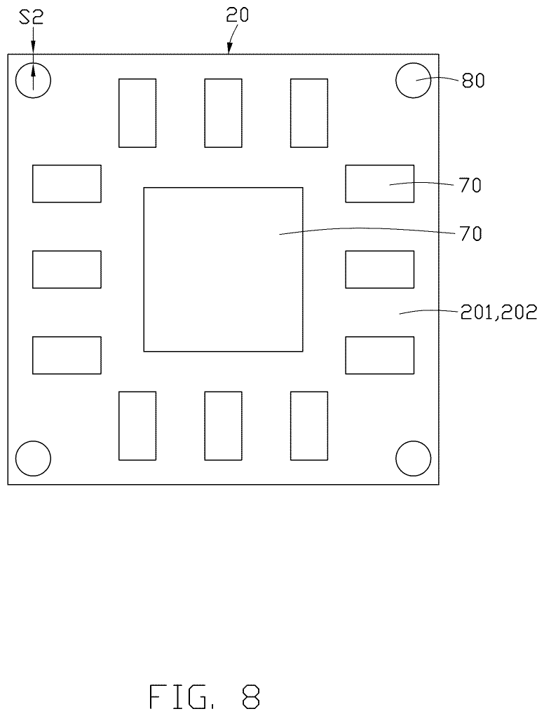

In FIG. 8, the second auxiliary pad 80 is round shaped, in order to avoid short-circuiting of elements on the circuit board 20, a distance S2 between the at least one second auxiliary pad 80 and an edge of the circuit board 20 is in the range of less than or equal to 3 mm. When the distance S2 between the second auxiliary pad 80 and the edge of the circuit board 20 is greater than 3 mm, it will make the spacing between the second pad 70 and the second auxiliary pad 80 is too small, which is prone to make a short circuit between the second pad 70 and the second auxiliary pad 80 during soldering due to solder melting conduction. Additionally, when the gap existing between the second auxiliary pad 80 and the edge of the circuit board 20 is less than or equal to 3 mm, the second auxiliary pad 80 at the edge of the circuit board 20 is not easily peeled off when the circuit board 20 is cut.

In FIG. 3 and FIG. 6, the first auxiliary pad 60 and the second auxiliary pad 80 have a same shape. In this way, the contact area of the first auxiliary pad 60 and the second auxiliary pad 80 is large, which can ensure that the first auxiliary pad 60 and the second auxiliary pad 80 are completely fitted together.

In FIG. 3 and FIG. 6, the first pad 50 and the second pad 70 have a same shape. In this way, the contact area of the first pad 50 and the second pad 70 is large, which can ensure that the first pad 50 and the second pad 70 are completely fitted together.

In some embodiments, the first auxiliary pad 60 may not be electrically connected to the circuitry within the component 10, the second auxiliary pad 80 may not be electrically connected to the circuitry within the circuit board 20. In some embodiments, the first auxiliary pad 60 may also serve as a circuit contact of the component 10, the second auxiliary pad 80 may also serve as a circuit contact of the circuit board 20.

In FIG. 1, FIG. 2 and FIG. 3, it can be understood that a distance between the first auxiliary pad 60 and the center of gravity O1 of the component 10 is greater than a distance between anyone of the plurality of first pads 50 and the center of gravity of the component 10. The circuit board 20 provided with a plurality of second pads 70 and four second auxiliary pads 80 spaced apart from the plurality of second pads 70 on a top surface 202 of the circuit board 20, the plurality of second pads 70 are correspondingly placed with the plurality of first pads 50, and the second auxiliary pad 80 is correspondingly placed the first auxiliary pad 60, and each of the plurality of second pads 70 is aligned with a corresponding first pads of the plurality of first pads 50, and the second auxiliary pad 80 is aligned with the first auxiliary pad 60 by a solder connection.

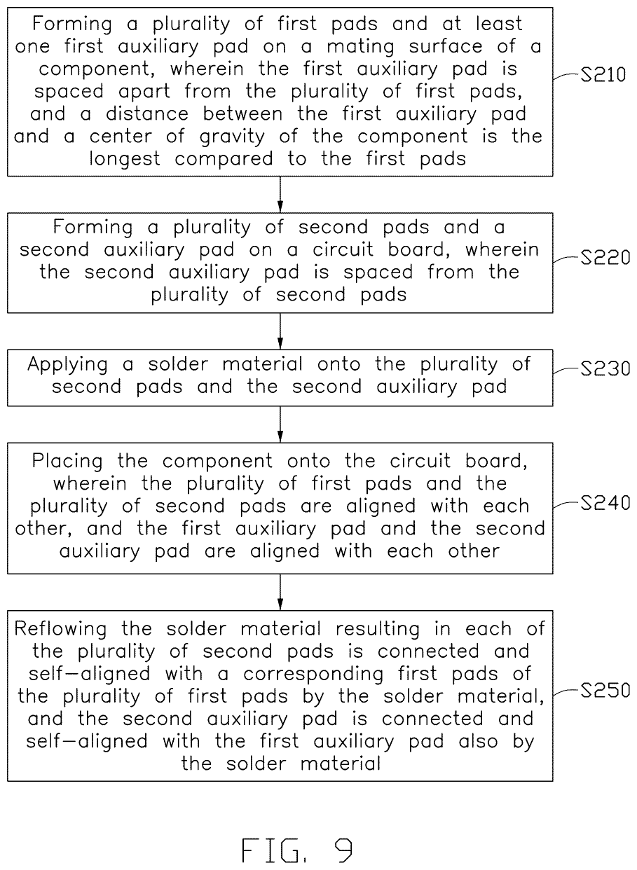

In FIG. 9, an embodiment of the disclosure also provides a manufacturing method of a semiconductor device 100, comprising the following steps:

S210, forming a plurality of first pads 50 and at least one first auxiliary pad 60 on a mating surface 101 of a component 10, wherein the first auxiliary pad 60 is spaced apart from the plurality of first pads 50, and a distance between the first auxiliary pad 60 and a center of gravity O1 of the component 10 is the longest compared to the first pad 50. In some embodiments, the plurality of first pads 50 and the first auxiliary pad 60 are formed by simultaneous etching.

S220, forming a plurality of second pads 70 and a second auxiliary pad 80 on a circuit board 20, wherein the second auxiliary pad 80 is spaced from the plurality of second pads 70.

In some embodiments, the plurality of second pads 70 and the second auxiliary pad 80 are formed by simultaneous etching.

In some embodiments, the order of steps S210 and S220 may be switched.

S230, applying a solder material onto the plurality of second pads 70 and the second auxiliary pad 80.

Wherein the thickness of the solder material can be set according to the actual need.

In some embodiments, the method further comprises applying solder to the first pad 50 or the first auxiliary pad 60.

S240, placing the component 10 onto the circuit board 20, wherein the plurality of first pads 50 and the plurality of second pads 70 are aligned with each other, and the first auxiliary pad 60 and the second auxiliary pad 80 are aligned with each other.

S250, reflowing the solder material resulting in each of the plurality of second pads 70 is connected and self-aligned with a corresponding first pads of the plurality of first pads 50 by the solder material, and the second auxiliary pad 80 is connected and self-aligned with the first auxiliary pad 60 also by the solder material.

Wherein, when the first pad 50 is aligned to the second pad 70, the first auxiliary pad 60 is also aligned to the second auxiliary pad 80.

Wherein, the solder material between the first pad 50 and the second pad 70 cools after melting, and the cooled solder material forms a solder paste or solder balls connecting the first pad 50 and the second pad 70; the solder material between the first auxiliary pad 60 and the second auxiliary pad 80 cools after melting, and the cooled solder material forms a solder paste or solder balls connecting the first auxiliary pad 60 and the second auxiliary pad 80.

In the method of the semiconductor device 100, due to the distance between the first auxiliary pad 60 and the center of gravity O1 of the component 10 is the longest compared to the first pads 50, the first auxiliary pad 60 can provide the maximum rotational torque for the rotation of the component 10 with respect to the circuit board 20, it is possible to improve the self-alignment capability between the component 10 and the circuit board 20, thereby improving the encapsulation accuracy of the component 10 and the circuit board 20, and expanding the encapsulation use of the component 10.

What is claimed is:

1. A semiconductor device, comprising:
a component provided with a plurality of first pads and at least one first auxiliary pad spaced from the plurality of first pads on a mating surface of the component, the first auxiliary pad is located on a first preset position of the mating surface of the component, and a distance between the first auxiliary pad at the first preset position and a center of gravity of the component is the longest compared to the first pads;
a circuit board provided with a plurality of second pads and a second auxiliary pad spaced from the plurality of second pads on a mating surface of the circuit board, the plurality of second pads are correspondingly placed with the plurality of first pads, and the second auxiliary pad is correspondingly placed with the first auxiliary pad;
a first solder material connected between the plurality of first pads and the plurality of second pads; and
a second solder material connected between the first auxiliary pad and the second auxiliary pad, wherein each of the plurality of second pads is aligned with a corresponding first pads of the plurality of first pads, and the second auxiliary pad is aligned with the first auxiliary pad by a solder connection.

2. The semiconductor device of claim 1, wherein the second auxiliary pad is located on a second preset position of the mating surface of the circuit board, the second preset position corresponds the first preset position.

3. The semiconductor device of claim 1, wherein the semiconductor device comprises a plurality of the first auxiliary pads, and the plurality of the first auxiliary pads is respectively located on corners of the mating surface of the component.

4. The semiconductor device of claim 3, wherein the plurality of first auxiliary pads is square shaped, rectangular shaped or round shaped, and centers of gravity of at least two of the plurality of first auxiliary pads are located on two opposite corners in a diagonal direction of the component, and centers of gravity of at least two of the plurality of first auxiliary pads and a center of gravity of the first pad located on the center of the component are in a straight line.

5. The semiconductor device of claim 1, wherein a distance between the at least one first auxiliary pad and an edge of the component is in the range of less than or equal to 3 mm.

6. The semiconductor device of claim 1, wherein a ratio of an area of the at least one first auxiliary pad to an area of one of the plurality of first pads is in a range from 0.01 to 5.

7. The semiconductor device of claim 1, wherein a minimum spacing value between one of the plurality of first pads and the at least one first auxiliary pad is A, a spacing value between any two of the plurality of first pads is B, wherein a ratio of A to B is in a range from 0.1 to 3.

8. The semiconductor device of claim 1, wherein the at least one first auxiliary pad and the plurality of first pads have an equal height relative to the mating surface of the component.

9. The semiconductor device of claim 1, wherein the at least one first auxiliary pad and the second auxiliary pad have a same shape.

10. The semiconductor device of claim 1, wherein one of the plurality of first pads is located on a center of the mating surface of the component, and other plurality of first pads are provided around the first pad that is located on the center of the component.

11. A semiconductor device, comprising:
a component provided with a plurality of first pads and at least one first auxiliary pad spaced from the plurality of first pads on a bottom surface of the component, and a distance between the first auxiliary pad and the center of gravity of the component is greater than a distance between anyone of the plurality of first pads and a center of gravity of the component; and
a circuit board provided with a plurality of second pads and a second auxiliary pad spaced from the plurality of second pads on a top surface of the circuit board, the plurality of second pads are correspondingly placed with the plurality of first pads, and the second auxiliary pad is correspondingly placed with the first auxiliary pad, and each of the plurality of second pads is aligned with a corresponding first pads of the plurality of first pads, and the second auxiliary pad is aligned with the first auxiliary pad by a solder connection.

12. The semiconductor device of claim 11, wherein the second auxiliary pad is located on a second preset position of the top surface of the circuit board, the second preset position corresponds the first preset position.

13. The semiconductor device of claim 11, wherein the semiconductor device comprises a plurality of the first auxiliary pads, and the plurality of the first auxiliary pads is respectively located on corners of the bottom surface of the component.

14. The semiconductor device of claim 13, wherein the plurality of first auxiliary pads is square shaped, rectangular shaped or round shaped, and centers of gravity of at least two of the plurality of first auxiliary pads are located on two opposite corners in a diagonal direction of the component, and centers of gravity of at least two of the plurality of first auxiliary pads and a center of gravity of the first pad located on the center of the component are in a straight line.

15. The semiconductor device of claim 11, wherein a distance between the at least one first auxiliary pad and an edge of the component is in the range of less than or equal to 3 mm.

16. The semiconductor device of claim 11, wherein a ratio of an area of the at least one first auxiliary pad to an area of one of the plurality of first pads is in a range from 0.01 to 5.

17. The semiconductor device of claim 11, wherein a minimum spacing value between one of the plurality of first pads and the at least one first auxiliary pad is A, a spacing value between any two of the plurality of first pads is B, wherein a ratio of A to B is in a range from 0.1 to 3.

18. The semiconductor device of claim 11, wherein the at least one first auxiliary pad and the plurality of first pads have an equal height relative to the bottom surface of the component.

19. A method of forming a semiconductor device, comprising:
forming a plurality of first pads and at least one first auxiliary pad on a mating surface of a component, wherein the first auxiliary pad is spaced apart from the plurality of first pads, and a distance between the first auxiliary pad and a center of gravity of the component is the longest compared to the first pads;
forming a plurality of second pads and a second auxiliary pad on a circuit board, wherein the second auxiliary pad is spaced from the plurality of second pads;
applying a solder material onto the plurality of second pads and the second auxiliary pad;
placing the component onto the circuit board, wherein the plurality of first pads and the plurality of second pads are aligned with each other, and the first auxiliary pad and the second auxiliary pad are aligned with each other; and
reflowing the solder material resulting in each of the plurality of second pads is connected and self-aligned with a corresponding first pads of the plurality of first pads by the solder material, and the second auxiliary pad is connected and self-aligned with the first auxiliary pad also by the solder material.

20. The method of claim 19, wherein the plurality of first pads and the first auxiliary pad are formed by simultaneous etching, the plurality of second pads and the second auxiliary pad are formed by simultaneous etching.
